(19) United States
(12) Patent Application Publication
(10) Pub. No.: US 2002/0000571 A1
(43) Pub. Date: Jan. 3, 2002

(54) High-temperature superconductor arrangement

(76) Inventors: Maken Chen, Baden-Dattwil (CH); Willi Paul, Wettingen (CH)

Correspondence Address: BURNS DOANE SWECKER & MATHIS L L P, POST OFFICE BOX 1404, ALEXANDRIA, VA, 22313-1404, US

(21) Appl. No.: 09/867,426

(22) Filed: May 31, 2001

(30) Foreign Application Priority Data
May 31, 2000 (DE) 100 27 243.6

(51) Int. Cl. H01L 31/0328; H01L 31/0336; H01L 31/072; H01L 31/109; H01L 21/336

(52) U.S. Cl. 257/192; 438/285

(57) ABSTRACT

In high-temperature superconductor arrangements having a superconductor 1 and having an electrical bypass 2, their thermal coefficients of expansion α_{SC}, α_{BP} are chosen such that the bypass applies compressive pressure to the superconductor. According to the invention, this situation occurs even when there is a considerable temperature difference ΔT between the bypass and the superconductor, as can be induced by fault currents in the case of current limiters. The thermomechanical compressive pressure prevents the formation or enlargement of cracks in the superconductor. The bypass is preferably made of steel, and is soldered or bonded onto the superconductor with a force fit.

### FIELD OF INVENTION

The present invention relates to the field of high-temperature superconduction. It relates in particular to a high-temperature superconductor arrangement as claimed in the precharacterizing clause of patent claim 1, and to a method for its production as claimed in the precharacterizing clause of patent claim 7.

### BACKGROUND OF THE INVENTION

A high-temperature superconductor arrangement for use in a current limiter is disclosed in European Patent Application EP-A 0 911 889. The arrangement comprises a superconducting layer and a perforated steel plate which is in the form of an electrical bypass and forms a conductor assembly with the superconducting layer. In order to improve the contact resistance between the superconductor and the bypass, the latter is bonded onto the superconductor by means of conductive epoxy resin. In order to cool it to the operating temperature, the conductor assembly is brought into thermal contact with a cooling medium, preferably with liquid nitrogen LN₂.

One weakness of the high-temperature superconductor is its susceptibility to the formation of cracks, resulting from the lack of ductility or plastic deformability of the ceramic material. Furthermore, when a tensile load is applied, stress peaks occur on microscopic cracks which already exist, and lead to these microscopic cracks growing further. Mechanical tensile stresses may occur, for example, due to electromagnetic forces or thermomechanical stresses in conjunction with temperature gradients and/or the superconductor and bypass having different thermal coefficients of expansion. Both polycrystalline superconductors and thin layers grown epitaxially on a substrate are affected, with the substrate dominating the resultant linear expansion in such layers when temperature changes occur, so that it must be prepared appropriately.

In order to reduce tensile or compressive loads in the superconductor, care is normally taken to ensure that the thermal coefficients of expansion of the superconductor and bypass match as well as possible. However, this promises to be successful only provided both components of the conductor assembly are at the same operating temperature.

DE 4418050 A1 discloses a hollow-cylindrical high-temperature superconductor to the outside of which an electrical bypass layer, with a thickness of 10-100 μm, in the form of a silver or an aluminum foil is applied. In order to reduce the contact resistance between the superconductor and the metallic bypass layer, mechanical reinforcement, which is subject to tensile stress and is composed of an elastic steel wire or a strip of glass-fiber fabric, is wound around the hollow cylinder at room temperature. The reinforcement is then fixed by means of a solder or a synthetic resin. This results in a compressive pressure in the superconductor material, with components at right angles to and parallel to the hollow-cylinder surface.

### SUMMARY OF THE INVENTION

The object of the present invention is to avoid the formation or enlargement of cracks at right angles to the current flow direction in the superconductor, in a high-temperature superconductor arrangement of the type mentioned initially. This object is achieved by a high-temperature superconductor arrangement having the features of patent claim 1, and by a method for its production having the features of patent claim 7.

The invention is based on the knowledge that the components of the conductor assembly are not necessarily always at the same temperature during operation. Particularly in the case of current limiters, the superconductor and the electrical bypass are heated at different rates in a limiting situation and, in the process, the bypass can reach a very much higher temperature than the superconductor.

The essence of the invention is to suppress tensile stresses in the high-temperature superconductor by subjecting it to a compressive pressure which is produced thermomechanically by the electrical bypass connected to the superconductor. The superconductor arrangement is designed such that this compressive pressure is maintained in all temperature configurations which can occur during cooling and during use of the arrangement and, in particular, in a limiting situation.

In a first preferred embodiment, the thermal coefficients of expansion of superconductor and bypass and the temperatures which occur during operation are matched to one another such that, when the arrangement cools down from a temperature T₀ to any possible combination of instantaneous superconductor and bypass temperatures, the specific change in length of the bypass is greater than that of the superconductor.

In a second preferred embodiment, the superconductor arrangement is designed and the operating conditions are chosen such that the maximum operating temperature of the bypass occurring in a limiting situation does not exceed a specific value which is proportional to the difference between the thermal coefficients of expansion of the bypass and superconductor.

The bypass should advantageously be applied symmetrically with respect to the superconductor, that is to say if the arrangement is flat and in strip form, on both sides of the superconductor, in order to avoid bimetallic distortions. If two superconducting layers separated by an insulator are surrounded by the bypass, the current in these two layers can flow in opposite directions in order to reduce alternating current losses.

The method according to the invention is distinguished by the superconductor and bypass being brought into contact at a production temperature T₀ and without any prestressing in the current flow direction. The match between the maximum temperature gradients to be expected and the thermal coefficients of expansion of the bypass and superconductor means that there is no need to subject the superconductor to pressure at the production temperature itself.

Further advantageous embodiments are described in the dependent patent claims.

### BRIEF DESCRIPTION OF THE DRAWINGS

The invention will be explained in more detail in the following text with reference to exemplary embodiments and in conjunction with the drawings, in which:

FIG. 1 shows a high-temperature superconductor arrangement having a bypass layer according to the invention for electrical stabilization and thermomechanical compression of the superconductor,

FIG. 2 shows a preferred embodiment of a high-temperature superconductor arrangement having an intermediate layer between the superconductor and bypass, and

FIG. 3 shows a high-temperature superconductor arrangement having two superconducting layers separated by an insulator.

The reference symbols used in the drawings are summarized in the List of Reference Symbols. In principle, identical parts are provided with the same reference symbols.

### DETAILED DESCRIPTION OF THE INVENTION

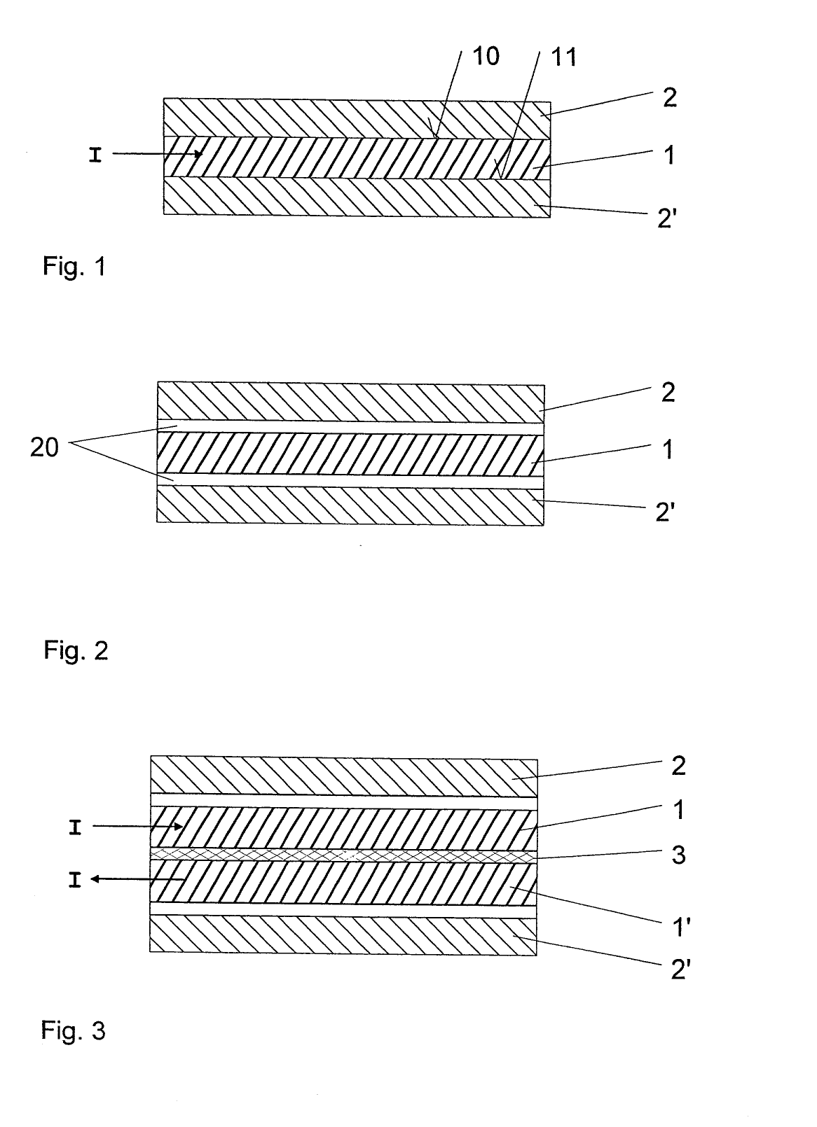

FIG. 1 shows a detail of a cross section through a high-temperature superconductor arrangement as is used, for example, in current limiters. A high-temperature superconductor 1 is connected with a positive lock and force fit over a large area via a first main surface 10 to an electrical bypass layer 2. The current flows in a current flow direction I parallel to the first main surface 10 through the conductor assembly comprising the superconductor 1 and the bypass 2. In arrangements in the form of wires with approximately square or circular cross sections, the bypass can surround the superconducting core on all sides. In the case of a flat, strip-like arrangement, it is advantageous to bring a further bypass layer 2′ into contact with the superconductor 1 via at least a second main surface 11 which is opposite the first main surface 10. This ensures that the thermally induced change in length occurs parallel to the current flow direction I and does not lead to any bimetallic distortion of the arrangement.

FIG. 2 shows intermediate layers 20 between the two layers 1, 2, in order to improve the electrical contact between the superconductor 1 and the bypass 2, and/or for mechanical fixing of the bypass 2. These intermediate layers 20 are composed, for example, of a solder layer or a cured, conductive polymer composite. Further layers, which are not shown in FIG. 2, are also possible, for example composed of glass-fiber plastic, and these are used for mechanical reinforcement of the arrangement.

FIG. 3 shows an arrangement having two superconducting layers 1, 1′, which are separated from one another by a layer of an electrical insulator 3. The current in these two layers 1, 1′ flows approximately equally, parallel and in opposite directions, or just in opposite directions, in the directions I, I′, thus reducing alternating current losses in the superconductor.

The fundamental problem of crack formation is not restricted to a specific type of high-temperature superconductor and/or to a specific method for its production. In current limiter applications, for example, melt-processed Bi₂Sr₂CaCu₂O₈ is used as a polycrystalline bulk material, with layer thicknesses preferably between 50 and 1000 μm. This is produced by passing a green sheet, composed of an appropriate superconductor powder and a binder as well as solvents, to a temperature treatment. In the process, the binder is burnt out first of all, and the superconductor is then partially melted in a controlled oxygen atmosphere. Metal alloys based on steel or nickel and having a resistivity of more than 10 μΩcm at room temperature are suitable for use as the normally conductive bypass. The bypass layer thickness is governed mainly by the total normally conductive bypass resistance required, and is between 0.1 and 2 mm.

In a limiting situation, that is to say following the occurrence of a fault current which exceeds the critical current density of the superconductor, a voltage drops starts to form, and the superconductor is heated by the resultant resistive heating. At the latest when the superconductor reaches the critical temperature T_{C}, the resistance in the superconductor becomes so large that the limited fault current now flows only through the metallic bypass. In consequence, only the bypass is now heated further, and considerable temperature gradients ΔT can build up between the instantaneous temperature of the bypass (T_{BP}) and that of the superconductor (T_{SC}). The superconductor temperature T_{SC} will therefore now increase only slowly and insignificantly above the critical temperature T_{C}. Said temperatures are not necessarily constant over the entire length of the conductor assembly, but in general vary as a function of position and time. In contrast, T_{BP} and T_{SC} can both be established simultaneously and at immediately adjacent points or the bypass and or the superconductor. Fault currents occur not only in current limiters, but must also be expected in superconducting transformers or transmission cables. As mentioned initially, such temperature differences lead to uncontrolled stresses on the superconductor, and to the formation or enlargement of cracks.

In order to avoid said stresses, the invention proposes that the electrical bypass 2 be used to produce a compressive pressure on the superconductor 1 and to ensure that said pressure is maintained even in a limiting situation, that is to say if the temperature T_{BP} of the bypass 2 is above the temperature T_{SC} of the superconductor 1. In contrast to the situation where the temperature of the conductor assembly is homogeneous (that is to say T_{BP}=T_{SC}), it is in general not sufficient for this purpose to choose the thermal coefficient of expansion α_{BP} of the bypass layer 2 to be only slightly greater than the thermal coefficient of expansion α_{SC} of the superconductor layer 1. For effective protection of the arrangement, it is essential to build up at least sufficient pressure in a main current flow direction I in order to suppress cracks at right angles to I. Pressure components at right angles to I may also be formed, depending on how said pressure is produced.

The assembly comprising the superconductor 1 and bypass 2 is fabricated at a specific production temperature, which is referred to as T₀ in the following text. This temperature T₀ may be room temperature or, as a function of the intermediate layer 20, the melting temperature of the solder or the curing temperature of the polymer composite. Once the assembly has been prepared, it is mechanically fixed, that is to say the components 1, 2 of the assembly no longer slide on one another, but they have the same relative change in length parallel to the main surface 10 when T≠T₀. Correspondingly, the intermediate layer 20 must not be flexible since, for example, an excessively thick layer of silver could prevent the desired build up of pressure in the superconductor, because of its deformability. If the thermal coefficients of expansion differ and/or if the components are at different temperatures, thermomechanical stresses are induced in both components. For example, when cooling down slowly to the operating temperature, a compressive load occurs in the body with the lower thermal coefficient of expansion, and a tensile load occurs in the other.

An estimate for the necessary design of the high-temperature superconductor arrangement is obtained from the following consideration: a superconductor and an electrical bypass of equal length are placed side by side at the temperature T₀ and are then cooled down to the temperatures T_{SC} (superconductor) and T_{BP} (bypass) respectively. Assuming the layers are mechanically connected with a force fit, this results in a compressive pressure on the superconductor, if the specific change in length of the bypass is greater than that of the superconductor:

α_{BP}·(T₀−T_{BP})>α_{SC}·(T₀−T_{SC}).

This first inequality is equivalent to:

$$\frac{{α}_{BP} - {α}_{SC}}{{α}_{BP}} > \frac{{T}_{BP} - {T}_{SC}}{{T}_{0} - {T}_{SC}} .$$

On the assumption that both the superconductor and the bypass are heated above T_{C} in a limiting situation, a condition, which is sufficient for the first inequality, for the maximum bypass temperature T_{BP}^{max} to be expected in this case is:

$$\frac{{T}_{BP}^{max} - {T}_{C}}{{T}_{0} - {T}_{C}} < \frac{{α}_{BP} - {α}_{SL}}{{α}_{BP}} .$$

The thermal coefficient of expansion α_{SC} of a ceramic superconductor is typically about 10·10⁻⁶/K, and that of a bypass made of steel α_{BP} is around 15·10⁻⁶/K. If T_{C}≈120 K and T₀≈300 K, the above estimate results in an acceptable temperature gradient T_{BP}^{max}−T_{C} of 60 K. The arrangement must therefore be designed such that T_{BP} does not rise above 180 K. The heat produced in the conductor assembly must therefore be dissipated sufficient quickly, and/or the fault current producing the heat must be interrupted quickly. If greater temperature differences cannot be avoided, said values for α_{SC} and/or α_{BP} must be modified appropriately.

Including the forces F which actually occur in the conductor assembly and which, apart from the mathematical sign, are of equal magnitude but are opposite, the first inequality is replaced by the condition that the specific change in length must be equal. A denotes the cross section at right angles to the current flow direction and E denotes the modulus of elasticity of the bypass/superconductor

α_{BP}·(T₀−T_{BP})−F/(A_{BP}·E_{BP})=α_{SC}·(T₀−T_{SC})+F/(A_{SC}·E_{SC})

The resultant change in length of the assembly is between the values occurring in the first inequality for separate components. The first inequality represents a necessary condition for the last-mentioned equation to have a solution with F>0, that is to say for there actually to be a compressive pressure on the superconductor. If T_{SC}=T₀=T_{BP}, the force F may assume any value. Prestressing at T₀ is thus possible, and, in this situation, a temperature T₀′ at which there is no prestressing can also always be found.

If T₀ is now identical to the production temperature of the arrangement, the latter is prepared by the bypass 2 being brought into contact with the superconductor 1 at T₀. This is done in a simple manner without any prestressing of the components, that is to say neither the superconductor 1 nor the bypass 2 is subjected to any pressure or stress in the current flow direction I at T₀. A force-fitting and positively locking connection is achieved by means of a thin intermediate layer 20 of solder or a conductive plastic such as epoxy resin with silver particles. The uniformly distributed material of the intermediate layer is heated or cured once, in a vacuum, at a temperature of 100-300° C. As an alternative to this, means such as presses or bindings are also feasible, which maintain a contact pressure at right angles to the main surfaces of the superconductor.

### LIST OF REFERENCE SYMBOLS

1, 1′ Superconductor

10, 11 Main surfaces

2, 2′ Electrical bypass

20 Intermediate layer

3 Insulator

1. A high-temperature superconductor arrangement having a superconductor (1) and having an electrical bypass (2) which is in electrical and mechanical contact with the superconductor (1), with the superconductor (1) being at a superconductor temperature T_{SC} and the bypass (2) being at a bypass temperature T_{BP}, characterized in that the bypass (2) produces a compressive pressure on the superconductor (1) in a current flow direction (I) even when the superconductor temperature T_{SC} is below the bypass temperature T_{BP}.

2. The arrangement as claimed in claim 1, with the superconductor (1) having a first thermal coefficient of expansion α_{SC} and the bypass (2) having a second thermal coefficient of expansion α_{BP} characterized in that, at a temperature T₀ which is above the maximum operating temperature of the bypass (2):
α_{BP}·(T₀−T_{BP})>α_{SC}·(T₀−T_{SC})

3. The arrangement as claimed in claim 2, with T_{C} being the critical temperature of the superconductor (1), characterized in that, for the maximum bypass temperature T_{BP}^{max}:
$$\frac{{T}_{BP}^{max} - {T}_{C}}{{T}_{0} - {T}_{C}} < \frac{{α}_{BP} - {α}_{SC}}{{α}_{BP}} .$$

4. The arrangement as claimed in claim 1, characterized in that the superconductor (1) is in strip form and has two main surfaces (10, 11) parallel to the current flow direction (I), and in that the bypass (2) is in contact with the superconductor (1) via both main surfaces (10, 11).

5. The arrangement as claimed in claim 4, characterized in that the superconductor has two layers which are separated by an electrical insulator and in which the current flows essentially in the opposite direction.

6. The arrangement as claimed in claim 1, characterized in that the bypass (2) is made of steel and there is a solder layer or an electrically conductive adhesive layer (20) between the superconductor (1) and the bypass (2).

7. A method for producing a high-temperature superconductor arrangement having a superconductor (1) and having an electrical bypass (2) which is in electrical and mechanical contact with the superconductor (1), with the superconductor (1) being at a superconductor temperature T_{SC} and having a first thermal coefficient of expansion α_{SC} and the bypass (2) being at a bypass temperature T_{BP} and having a second thermal coefficient of expansion α_{BP},
characterized in that the bypass (2) produces a compressive pressure on the superconductor (1) in a current flow direction (I) even when the superconductor temperature T_{SC} is below the bypass temperature T_{BP}, and in that the superconductor (1) and the bypass (2) are brought into mechanical contact, without any pressure in the current flow direction (I), at a production temperature T₀ which is above the maximum operating temperature of the bypass (2).

8. The method as claimed in claim 7, characterized in that the bypass (2) is made of steel and is brought into contact with the superconductor (1) by means of soldering or bonding.
